(19) United States
(12) Patent Application Publication
(10) Pub. No.: US 2022/0201886 A1
(43) Pub. Date: Jun. 23, 2022

(54) COVER, COVER-ATTACHED PART, AND RADAR DEVICE

(71) Applicant: NITTO DENKO CORPORATION, Ibaraki-shi, Osaka (JP)

(72) Inventor: Kazuhiro Fuke, Osaka (JP)

(73) Assignee: NITTO DENKO CORPORATION, Ibaraki-shi, Osaka (JP)

(21) Appl. No.: 17/599,068

(22) PCT Filed: Mar. 18, 2020
(86) PCT No.: PCT/JP2020/012162

§ 371 Date: Sep. 28, 2021

(30) Foreign Application Priority Data
Mar. 29, 2019 (JP) 2019-068939

(51) Int. Cl. H05K 5/03; H05K 9/00

(52) U.S. Cl. CPC H05K 5/03; G01S 13/931; H05K 9/0007

(57) ABSTRACT

A cover 1a includes a radio wave absorber 10. The cover 1a is capable of being disposed along a plane and is capable of forming a 3D structure T having a plurality of flat faces 5. The cover 1a includes coupling portions 21, 22a, and 22b coupling the flat faces 5 adjacent to each other in the 3D structure T. The three-dimensional structure T includes a first opening 15a and a second opening 15b.

### TECHNICAL FIELD

The present invention relates to a cover, a cover-attached part, and a radar device.

### BACKGROUND ART

A technique of using a radar to detect obstacles has been known.

For example, Patent Literature 1 describes an obstacle detection device for vehicles, the obstacle detection device including a radar device that detects obstacles by transmitting a radio wave. This device includes a shielding plate that shields against a predetermined incoming wave. This can prevent the obstacle detection device for vehicles from mistakenly detecting, for example, structures, such as curbs, on roads as targets. A radio wave absorber may be used as the shielding plate.

Patent Literature 2 describes a device for vehicles, the device including a radar sensor. This device for vehicles includes an absorptive element for absorbing an interference wave. The absorptive element is formed of a flexible plastic material. The absorptive element is coated with a radiation absorbing material. The absorptive element forms a circumferential seal by means of which the field of vision of the radar sensor is completely shielded against coherent radiation from the rear side.

Patent Literature 3 describes an electromagnetic wave absorber for enhancing the reliability of anti-collision systems. This electromagnetic wave absorber can be mounted on a car body member, such as a bumper, that is a resin formed body or a metal formed body.

### CITATION LIST

### Patent Literature

Patent Literature 1: JP 2015-212705 A

Patent Literature 2: JP 2015-534052 A

Patent Literature 3: JP 2017-112373 A

### SUMMARY OF INVENTION

### Technical Problem

It is conceivable, as in the techniques described in Patent Literatures 1 to 3, to use, for example, a cover for shielding against an unnecessary radio wave for sensing using a radio wave. This cover has, for example, a predetermined three-dimensional structure. Attaching a radio wave absorber to a formed body having a predetermined three-dimensional structure to produce the cover is a complicated operation. Performing an appearance test of the radio wave absorber attached to the cover or a test of the radio wave absorption performance is also a complicated operation.

In view of these circumstances, the present invention provides a technique that allows easy production of a cover having a predetermined three-dimensional structure and including a radio wave absorber or that makes it easy to perform an appearance test of a radio wave absorber or a test of the radio wave absorption performance.

### Solution to Problem

The present invention provides a cover including:

a radio wave absorber; and

a coupling portion, wherein

the cover is capable of being disposed along a plane and is capable of forming a three-dimensional structure having a plurality of flat faces,

the coupling portion couples the flat faces adjacent to each other in the three-dimensional structure, and

the three-dimensional structure includes a first opening and a second opening.

The present invention also provides a cover-attached part including:

the above cover; and

a vehicle part to which the cover is attached.

The present invention also provides a radar device including:

a radar; and

the above cover formed as a three-dimensional structure having a plurality of flat faces, the three-dimensional structure including a first opening and a second opening, the cover being disposed to be capable of absorbing a portion of a radio wave emitted from the radar or a portion of a radio wave reflected toward the radar.

### Advantageous Effects of Invention

According to the above cover, a cover including a radio wave absorber having a predetermined three-dimensional structure can be easily produced. Moreover, the above cover makes it easy to perform an appearance test of the radio wave absorber or a test of the radio wave absorption performance.

### BRIEF DESCRIPTION OF DRAWINGS

FIG. 1 is a plan view showing an example of a cover according to the present invention disposed along a plane.

FIG. 2 is a perspective view showing a three-dimensional structure formed using the cover shown in FIG. 1.

FIG. 3 is a cross-sectional view showing the cover along a line III-III in FIG. 1.

FIG. 4 is a cross-sectional view showing an example of a cover-attached part according to the present invention.

FIG. 5 a cross-sectional view showing an example of a radar device according to the present invention.

FIG. 6 is a plan view showing another example of the cover according to the present invention disposed along a plane.

FIG. 7 is a plan view showing yet another example of the cover according to the present invention disposed along a plane.

FIG. 8 is a cross-sectional view showing yet another example of the cover according to the present invention.

FIG. 9 is a plan view showing yet another example of the cover according to the present invention disposed along a plane.

### DESCRIPTION OF EMBODIMENTS

Hereinafter, embodiments of the present invention will be described with reference to the drawings. The present invention is not limited to the following embodiments.

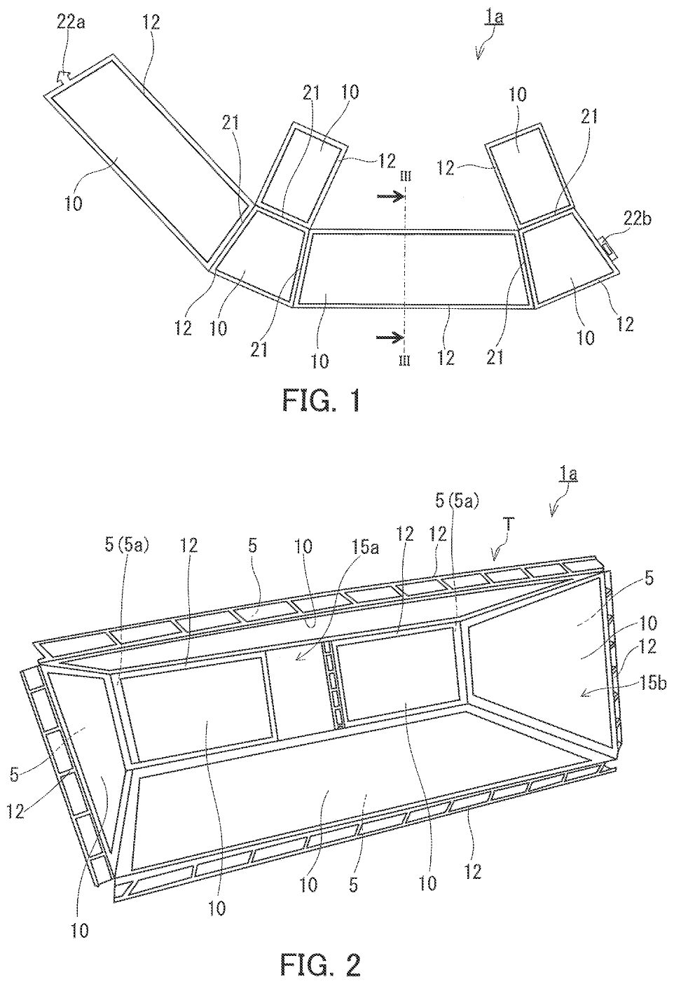

As shown in FIGS. 1 and 2, a cover 1a includes a radio wave absorber 10. The cover 1a is capable of being disposed along a plane. Additionally, the cover 1a is capable of forming a three-dimensional structure T having a plurality of flat faces 5. The cover 1a includes coupling portions 21, 22a, and 22b. These coupling portions couple the flat faces 5 adjacent to each other in the three-dimensional structure T. The three-dimensional structure T includes a first opening 15a and a second opening 15b.

As shown in FIG. 1, the cover 1a includes, for example, the plurality of flat face portions separated by the coupling portions, and the three-dimensional structure T can be formed by bending the coupling portions. FIG. 1 shows a state of the cover 1a yet to be formed as the three-dimensional structure T, and FIG. 2 shows a formed product having the three-dimensional structure T formed of the cover 1a. Herein, the three-dimensional structure T is typically a structure in which two flat faces 5 adjacent to each other are disposed along two intersecting planes.

The cover 1a is capable of being disposed along a plane, as shown in FIG. 1. For example, the radio wave absorber 10 can be attached to the cover 1a in this sheet state, so that the cover 1a can be easily produced. Moreover, it is easy to perform an appearance test of the radio wave absorber 10 or a test of the radio wave absorption performance. The sheet of the cover 1a may or may not include the radio wave absorber 10 beforehand. When the sheet of the cover 1a includes the radio wave absorber 10 beforehand, it is unnecessary to attach the radio wave absorber 10. When the sheet of the cover 1a does not include the radio wave absorber 10 beforehand, the radio wave absorber 10 is to be attached thereto.

The coupling portions are not limited to a particular embodiment as long as the coupling portions can couple the flat faces 5 adjacent to each other. The coupling portion 21 is, for example, a portion which can be bent such that two flat faces 5 adjacent to each other make a predetermined angle in the three-dimensional structure T. In the sheet of the cover 1a, the coupling portion 21 is configured, for example, to be more easily bent than a portion other than the coupling portion 21. The coupling portion 21 is formed, for example, along a border between two flat faces 5 to be adjacent to each other in the three-dimensional structure T. The coupling portion 21 may be, for example, a slit formed continuously or discontinuously along a border between two flat faces 5 to be adjacent to each other in the three-dimensional structure T. When the slit is formed discontinuously, the slit may extend through the sheet of the cover 1a in the thickness direction. The coupling portion 21 may be formed as a thin portion which is thinner than the other portions of the sheet of the cover 1a. For example, the coupling portion 21 can be formed by half-cutting.

The coupling portions 22a and 22b can be, for example, engaged with each other in the three-dimensional structure T. In this case, the shape of the three-dimensional structure T is likely to be maintained. For example, the coupling portion 22a has a projection having a predetermined shape, and the coupling portion 22b has a hole. In this case, the projection of the coupling portion 22a is inserted in the hole of the coupling portion 22b, so that a tip of the projection of the coupling portion 22a is engaged with the coupling portion 22b.

Each coupling portion may be formed of an adhesive tape or may be a portion formed to be heat-sealable in the sheet of the cover 1a. In the three-dimensional structure T, different types of coupling portions may be used in combination. For example, in the three-dimensional structure T, some of the coupling portions can be bent, some are formed of an adhesive tape, and some may be formed in an engageable manner.

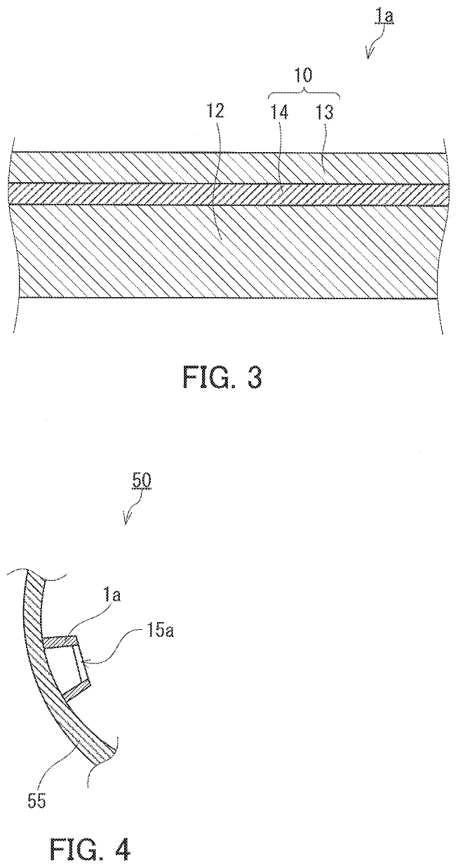

The radio wave absorber 10 is not limited to a particular embodiment as long as the radio wave absorber 10 can absorb a radio wave. The radio wave absorber 10 absorbs, for example, a radio wave unnecessary for sensing using a radar. As shown in FIG. 3, the radio wave absorber 10 includes, for example, a reflective layer 14 that reflects a radio wave and a remaining portion 13 other than the reflective layer 14. The radio wave absorber 10 may be a λ/4 radio wave absorber or a radio wave absorber including a dielectric loss material or a magnetic loss material. When the radio wave absorber 10 is a λ/4 radio wave absorber, the radio wave absorber 10 includes, for example, the reflective layer 14 that reflects a radio wave, a resistive layer, and a dielectric layer disposed between the reflective layer and the resistive layer. In this case, the remaining portion 13 includes, for example, the resistive layer and the dielectric layer. The resistive layer is a layer adjusted so that an impedance expected on its front surface will be equal to a characteristic impedance of a plane wave. The resistive layer is formed of, for example, a metal oxide, an electrically conductive polymer, a carbon nanotube, a metal nanowire, or a metal mesh. When the radio wave absorber 10 is a radio wave absorber including a dielectric loss material, the radio wave absorber 10 includes, for example, the reflective layer 14 that reflects a radio wave and an absorbing layer lying on the reflective layer. The absorbing layer includes a matrix such as resin or rubber and a dielectric loss material, such as carbon particles, dispersed in the matrix. In this case, the remaining portion 13 includes, for example, the absorbing layer. When the radio wave absorber 10 is a radio wave absorber including a magnetic loss material, the radio wave absorber 10 includes, for example, the reflective layer 14 that reflects a radio wave and an absorbing layer lying on the reflective layer. The absorbing layer includes a matrix such as resin or rubber and a magnetic loss material, such as ferrite, iron, or nickel particles, dispersed in the matrix. In this case, the remaining portion 13 includes the absorbing layer.

The absolute value of the return loss of the radio wave absorber 10 for a radio wave to be absorbed is, for example, 0.1 dB or more. The radio wave absorber 10 may have a configuration in which a resin layer or resin formed body not including a magnetic loss material nor a dielectric loss material and a reflective layer including a metal that reflects a radio wave are stacked. The absolute value of the return loss of the radio wave absorber 10 for a radio wave to be absorbed may be 1 dB or more, 5 dB or more, 10 dB or more, or 20 dB or more.

As shown in FIG. 3, the cover 1a further includes, for example, a support 12 supporting the radio wave absorber 10. The support 12 may be in contact with the radio wave absorber 10, or another layer may be disposed between the support 12 and the radio wave absorber 10. When the cover includes the support 12, the radio wave absorber 10 is likely to be protected by the support 12.

The support 12 is not limited to a particular embodiment as long as the support 12 can support the radio wave absorber 10. For example, the support 12 includes a non-metal material. In this case, the sheet of the cover 1a is easily bent at the coupling portion 21. Moreover, the cover 1a is likely to have a reduced weight and the manufacturing cost of the cover 1a is likely to be reduced.

The non-metal material included in the support 12 may be, for example, resin or fibers such as paper.

The support 12 may be solid, hollow, or partially hollow. When the support 12 is partially hollow, the support 12 is, for example, paper or plastic corrugated board. The support 12 is desirably plastic corrugated board. In that case, the cover 1a is likely to have a reduced weight and the support 12 is likely to have desired stiffness. Moreover, the support 12 is likely to have good durability. The plastic corrugated board can be, for example, shaped integrally by extrusion or the like. Therefore, the support 12 can be manufactured easily. The plastic corrugated board may be formed, for example, by joining a pair of flat liners to both longitudinal edges of a rib extending to a particular direction.

For example, when the radio wave absorber 10 is a λ/4 radio wave absorber, the radio wave absorber includes, in some cases, a fragile material such as an ITO film. Even in such cases, the support 12 formed of plastic corrugated board has desired stiffness. That can reduce deformation of the radio wave absorber 10. Consequently, damage, such as breakage, of the radio wave absorber 10 can be effectively reduced. That makes it likely for the cover 1a to exhibit desired radio wave absorption performance for a long period of time.

The support 12 has a mass per unit area of, for example, 3 kg/m² or less. In that case, the cover 1a is likely to have a reduced weight. The mass per unit area of the support 12 may be 2 kg/m² or less or 1 kg/m² or less. The support 12 has a mass per unit area of, for example, 0.1 kg/m² or more. In that case, the cover 1a is likely to have desired stiffness. The mass per unit area of the support 12 may be 0.2 kg/m² or more or 0.3 kg/m² or more.

The support 12 has a flexural rigidity of, for example, 30 N·mm² or more. In this case, the cover 1a is likely to have desired stiffness and the shape of the three-dimensional structure T is likely to be maintained appropriately. The flexural rigidity of the support 12 may be 500 N·mm² or more or 1500 N·mm² or more. The support 12 has a flexural rigidity of, for example, 40000 N·mm² or less. In this case, the sheet of the cover 1a is easily bent when the three-dimensional structure T is formed. The flexural rigidity of the support 12 may be 20000 N·mm² or less or 10000 N·mm² or less.

The flexural rigidity of the support 12 can be determined, for example, in the following manner. A specimen having a rectangular shape when viewed in plan is obtained by cutting the support 12. One longitudinal end of the specimen is fixed to form a cantilever, and a downward given load is applied by a weight at the other longitudinal end of the specimen to bend and deform the specimen. The resulting deflection of the bent and deformed specimen is measured. On the basis of the measurement conditions and the measurement result, the flexural rigidity EI of the support 12 can be determined by the following formula (1). In the formula (1), W represents the basis weight [g/m²] of a specimen, L represents the length [cm] of an overhang of the specimen, b represents the width [cm] of the specimen, F represents the weight [g] of a weight, and d represents the deflection [cm].

EI={(WLb/8)×10⁻⁴+(F/3)}×(L³/d)×9.81/10 (1)

As shown in FIG. 3, in the cover 1a, the reflective layer 14 is disposed between the support 12 and the remaining portion 13 of the radio wave absorber 10. This makes it easier for the radio wave absorber 10 to effectively absorb a radio wave. Moreover, this can prevent a radio wave from passing through the cover 1a .

The reflective layer 14 is not limited to a particular embodiment as long as the reflective layer 14 reflects a radio wave. The reflective layer 14 is, for example, a metallic foil or an alloy foil. The reflective layer 14 may be formed, for example, by forming an electrical conductor film on the support 12 by a method such as sputtering, ion plating, plating, or coating (for example, bar coating). The reflective layer 14 may be formed by rolling. The reflective layer 14 may be formed by adhering an adhesive tape having a metallic foil such as an aluminum foil or a thin metal film such as a thin aluminum film.

The radio wave absorber 10 may have given adhesion strength to the support 12. For example, adhesion strength of the radio wave absorber 10 to the support 12 is 0.1 [N/20 mm] or more, the adhesion strength being obtained by measuring 180° peel adhesion strength. In this case, the radio wave absorber 10 is unlikely to be peeled off from the support 12, and the cover 1a is likely to exhibit desired radio wave absorption performance. The measurement of the 180° peel adhesion strength can be performed, for example, according to Japanese Industrial Standards (JIS) Z 0237: 2009. For example, the support 12 is used instead of a testing plate used in the measurement of 180° peel adhesion strength specified in JIS Z 0237: 2009. In this case, the support 12 is, for example, fixed using a given jig or the like. The support 12 may be joined to a given substrate using an adhesive agent or the like.

The adhesion strength of the radio wave absorber 10 to the support 12 may be 1 [N120 mm] or more, 2 [N120 mm] or more, or 5 [N120 mm] or more, the adhesion strength being obtained by measuring 180° peel adhesion strength.

As shown in FIG. 2, the three-dimensional structure T is a hollow structure, and, in the three-dimensional structure T, the radio wave absorber 10 is located between an interior space of the hollow structure and the support 12. This makes it likely that a radio wave is effectively absorbed inside the hollow structure. Moreover, the radio wave absorber 10 can be appropriately protected by the support 12. Furthermore, the support 12 can keep the radio wave absorber 10 disposed at an appropriate position.

As shown in FIG. 1, for example, the coupling portions 21, 22a, and 22b are not covered by the radio wave absorber 10. In this case, the radio wave absorber 10 is less likely to peel off from the support 12. The coupling portions are, as described above, portions for coupling the flat faces 5 adjacent to each other. Thus, when the coupling portions 21, 22a, and 22b are covered by the radio wave absorber 10, the radio wave absorber 10 can peel off from the support 12 by bending the coupling portion 21 or by inserting the projection of the coupling portion 22a into the hole of the coupling portion 22b.

As shown in FIG. 2, in the three-dimensional structure T, the plurality of flat faces 5 include a first flat face 5a disposed along a plane including an opening face of the first opening 15a. In this case, the size of the first opening 15a is easily adjusted to a desired size by a section of the cover 1, the section being the first flat face 5a. In the present embodiment, the cover 1a includes, for example, two first flat faces 5a. The opening face of the first opening 15a is sandwiched between the two first flat faces 5a. Therefore, the size of the opening face of the first opening 15a can be easily adjusted to a desired size by properly adjusting the sizes of the two first flat faces 5a.

In the three-dimensional structure T, the positional relation between the first opening 15a and the second opening 15b is not limited to a particular relation. For example, when the three-dimensional structure T has the shape of a truncated pyramid, the first opening 15a is arranged on the upper base of the truncated pyramid, the second opening 15b is arranged on the lower base of the truncated pyramid. For example, as described later, an antenna of a radar is disposed on the first opening 15a, and a vehicle part such as a bumper is disposed on the second opening.

For example, a cover-attached part can be provided using the cover 1a. As shown in FIG. 4, a cover-attached part 50 includes, for example, the cover 1a and a vehicle part 55. The vehicle part 55 is not limited to a particular part. Examples of the vehicle part 55 include bumpers, grilles, fenders, spoilers, and emblems.

For example, a radar device can be provided using the cover 1a. As shown in FIG. 5, a radar device 70 includes, for example, a radar 75 and the cover 1a. In the radar device 70, the cover 1a is formed as the three-dimensional structure T, and is disposed to be capable of absorbing a portion of a radio wave emitted from the radar or a portion of a radio wave reflected toward the radar. This allows the cover 1a to absorb an unnecessary radio wave and allows the radar device 70 to exhibit high reliability

For example, an antenna of the radar 75 is disposed at the first opening 15a.

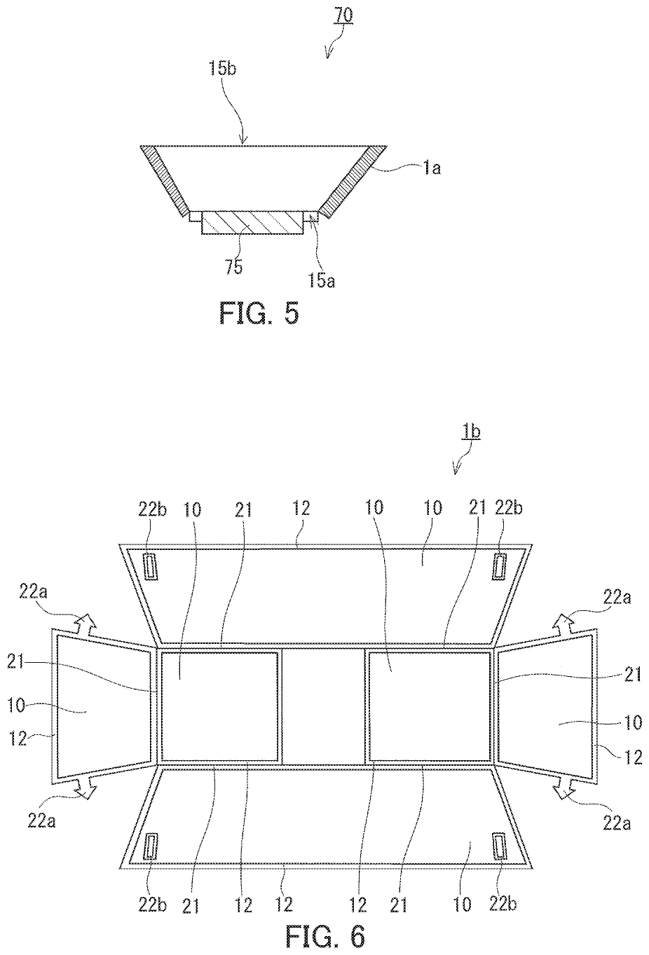

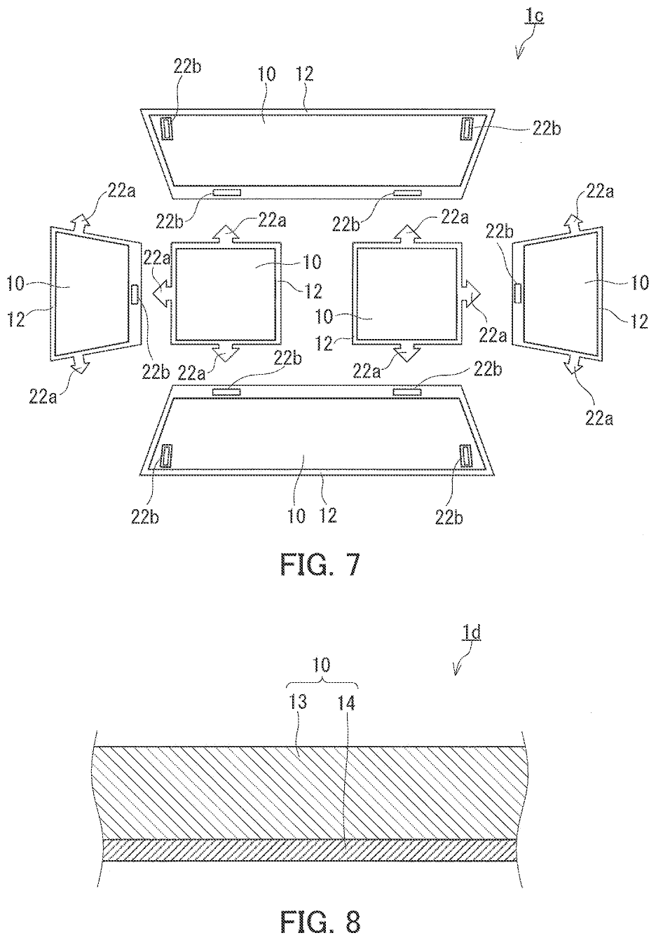

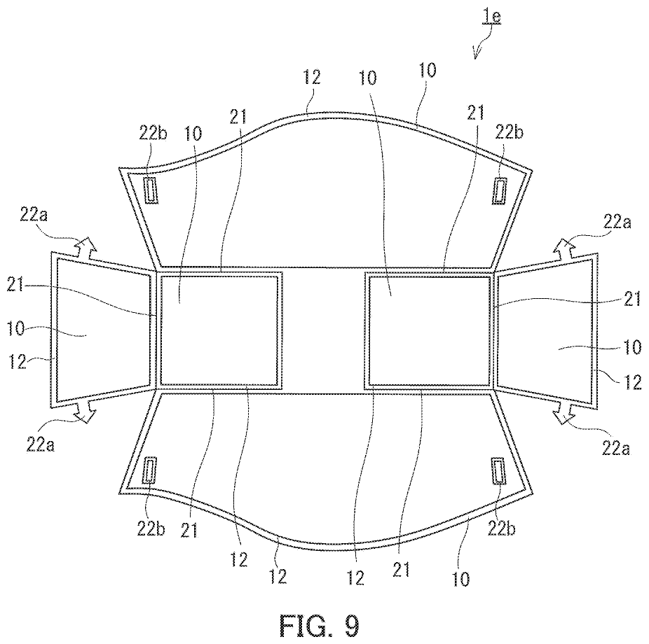

The cover 1a can be modified in various respects. For example, the cover 1a may be modified to a cover 1b shown in FIG. 6, a cover 1c shown in FIG. 7, a cover 1d shown in FIG. 8, and a cover 1e shown in FIG. 9. The covers 1b to 1e are configured in the same manner as the cover 1a unless otherwise described. The components of the covers 1b to 1e that are the same as or correspond to the components of the cover 1a are denoted by the same reference characters, and detailed descriptions of such components are omitted. The description given for the cover 1a is applicable to the covers 1b to 1e unless there is a technical inconsistency.

As shown in FIG. 6, in the cover 1b, all sections being the sides of the three-dimensional structure T are connected to a section being the upper base of the truncated pyramid that is the three-dimensional structure T. In this case, when the cover 1b is disposed along a plane, the dimensions of the cover 1b are unlikely to be large in a specific direction, and it is easy to perform an operation for production of the cover 1b or for an appearance test of the radio wave absorber 10 or a test of the radio wave absorption performance.

As shown in FIG. 7, the cover 1c includes a plurality of pieces. Each piece is one of the flat faces 5 in the three-dimensional structure T. Each piece has at least one of the coupling portion 22a and the coupling portion 22b. The three-dimensional structure T is formed by inserting the projection of the coupling portion 22a of one piece in the hole of the coupling portion 22b of another piece and engaging the projection and the hole. In this case, material loss can be reduced because, when a defect is found in one piece through an appearance test of the radio wave absorber 10 or a test of the radio wave absorption performance, only that piece is required to be replaced.

As shown in FIG. 8, the three-dimensional structure T formed of the cover 1d is a hollow structure. In the three-dimensional structure T, the remaining portion 13 of the radio wave absorber 10 is located between an interior space of the hollow structure and the reflective layer 14.

In the cover 1d, the remaining portion 13 of the radio wave absorber 10 may be configured in the same manner as the support 12. For example, the remaining portion 13 of the radio wave absorber 10 can be formed of plastic corrugated board. In this case, the cover 1d exhibits a predetermined level of radio wave absorption performance and the reflective layer 14 can prevent an unnecessary radio wave from passing through the cover 1d. In this case, the plastic corrugated board may include at least one of a magnetic loss material and a dielectric loss material or may include neither a magnetic loss material nor a dielectric loss material. A radio wave absorber having a configuration composed of the reflective layer and the plastic corrugated board including neither a magnetic loss material nor a dielectric loss material falls under the category of the radio wave absorber of the present specification because the absolute value of the return loss thereof for a radio wave to be absorbed is about 0.6 dB.

As shown in FIG. 9, in the cover 1e, an outline of a section being a side of the three-dimensional structure T includes a curve. In this case, the cover 1e is easily attached to a part with a curved surface such that the cover 1e conforms the curved surface of the part. The cover 1e having such a shape can be manufactured by adjusting a blanking die, and thus the manufacturing cost of the cover 1e can be kept low.

The cover 1a may be modified to include a radio shield instead of the radio wave absorber 10. The radio shield includes, for example, a reflective layer that reflects a radio wave. This reflective layer may be configured, for example, in the same manner as the reflective layer 14 of the cover 1a. Moreover, the cover may further include a support supporting the radio shield. This support may be configured in the same manner as the support 12 of the cover 1a. For example, the support can be formed of plastic corrugated board. A three-dimensional structure that can be formed of the cover including the radio shield may be a hollow structure. In this case, the support may be located between the reflective layer and an interior space of the hollow structure, or the reflective layer may be located between the support and the interior space of the hollow structure. For example, in the cover including the radio shield, the support may be formed of plastic corrugated board and be located between the reflective layer and the interior space of the hollow structure. In this case, desired radio wave absorption performance can be exhibited thanks to the support and the reflective layer.

The present invention can be expressed as follows in the case of an embodiment including the above radio shield.

A cover including: a radio wave absorber or a radio shield; and a coupling portion, wherein the cover is capable of being disposed along a plane and is capable of forming a three-dimensional structure having a plurality of flat faces, the coupling portion couples the flat faces adjacent to each other in the three-dimensional structure, and the three-dimensional structure includes a first opening and a second opening.

In this case, the absolute value of the return loss of the radio wave absorber for a radio wave to be absorbed is, for example, 10 dB or more and preferably 20 dB or more.

1. A cover comprising:
a radio wave absorber; and
a coupling portion, wherein
the cover is capable of being disposed along a plane and is capable of forming a three-dimensional structure having a plurality of flat faces,
the coupling portion couples the flat faces adjacent to each other in the three-dimensional structure, and
the three-dimensional structure includes a first opening and a second opening.

2. The cover according to claim 1, further comprising a support supporting the radio wave absorber.

3. The cover according to claim 2, wherein the support includes a non-metal material.

4. The cover according to claim 2, wherein
the radio wave absorber includes a reflective layer that reflects a radio wave and a remaining portion other than the reflective layer, and
the reflective layer is disposed between the support and the remaining portion.

5. The cover according to claim 2, wherein adhesion strength of the radio wave absorber to the support is 0.1 [N/20 mm] or more, the adhesion strength being obtained by measuring 180° peel adhesion strength.

6. The cover according to claim 2, wherein
the three-dimensional structure is a hollow structure, and
in the three-dimensional structure, the radio wave absorber is located between an interior space of the hollow structure and the support.

7. The cover according to claim 1, wherein
the radio wave absorber includes a reflective layer that reflects a radio wave and a remaining portion other than the reflective layer,
the three-dimensional structure is a hollow structure, and
in the three-dimensional structure, the remaining portion is located between an interior space of the hollow structure and the reflective layer.

8. The cover according to claim 2, wherein the coupling portion is not covered by the radio wave absorber.

9. The cover according to claim 1, wherein in the three-dimensional structure, the plurality of flat faces include a first flat face disposed along a plane including an opening face of the first opening.

10. A cover-attached part comprising:
the cover according to claim 1; and
a vehicle part to which the cover is attached.

11. A radar device comprising:
a radar; and
the cover according to claim 1 formed as a three-dimensional structure having a plurality of flat faces, the three-dimensional structure including a first opening and a second opening, the cover being disposed to be capable of absorbing a portion of a radio wave emitted from the radar or a portion of a radio wave reflected toward the radar.
